(19) United States
(12) Patent Application Publication
(10) Pub. No.: US 2026/0221721 A1
(43) Pub. Date: Jul. 30, 2026

(54) SURFACE-EMITTING LASER DEVICE

(71) Applicants: KYOTO UNIVERSITY, Kyoto-shi, Kyoto (JP); STANLEY ELECTRIC CO., LTD., Meguro-ku, Tokyo (JP)

(72) Inventors: Susumu NODA, Kyoto (JP); Tomoaki KOIZUMI, Tokyo (JP); Kei EMOTO, Tokyo (JP)

(73) Assignees: KYOTO UNIVERSITY, Kyoto-shi, Kyoto (JP); STANLEY ELECTRIC CO., LTD., Meguro-ku, Tokyo (JP)

(21) Appl. No.: 19/141,334

(22) PCT Filed: Dec. 5, 2023
(86) PCT No.: PCT/JP2023/043548

§ 371 Date: Jun. 20, 2025

(30) Foreign Application Priority Data
Dec. 21, 2022 (JP) 2022-204011

(51) Int. Cl. H01S 5/11; H01S 5/02345; H01S 5/0236; H01S 5/042

(52) U.S. Cl. CPC H01S 5/11; H01S 5/0236; H01S 5/04253; H01S 5/04254; H01S 5/02345

(57) ABSTRACT

A photonic-crystal surface-emitting laser device has a surface-emitting laser element, a mounting substrate on which the surface-emitting laser element is placed and electrically connected, and a conductive element-bonding member bonding the surface-emitting laser element and the mounting substrate that mitigates strain in the surface-emitting laser element due to the mounting substrate. The surface-emitting laser element includes a translucent element substrate, a first semiconductor layer on the element substrate, an active layer on the first semiconductor layer, a second semiconductor layer of conductive type opposite to the first semiconductor layer, provided on the active layer, an air-hole layer included in the first or second semiconductor layer including air hole disposed with two-dimensional periodicity in a plane, and a light reflection layer provided on the second semiconductor layer having a reflection surface, and has a light emission surface on surface side opposite to the first semiconductor layer side of the element substrate.

### TECHNICAL FIELD

The present invention relates to a surface-emitting laser device, and particularly to a surface-emitting laser device having a photonic-crystal surface-emitting laser element.

### BACKGROUND ART

In recent years, the development of photonic-crystal surface-emitting lasers (PCSEL) using photonic crystals (PC) has progressed.

For example, Patent Literature 1 discloses formation of a photonic crystal layer having a uniform size and a uniform refractive index period by forming air holes having two-dimensional periodicity in a guide layer, forming concave portions having facets with a predetermined surface orientation in upper portions of openings of the air holes, and flattening the concave portions by mass transport.

In addition, Non Patent Literature 1 discloses formulation of diffracted light of a photonic-crystal surface-emitting laser, a diffracted radiation wave profile that is diffracted in a photonic crystal layer and emitted in a direction perpendicular to the photonic crystal layer, and the like.

### CITATION LIST

### Patent Literatures

Patent Literature 1: Japanese Patent No. 7101370
Non Patent Literature 1: Y. Liang et al.: Phys. Rev. B vol. 84, 195119 (2011)

### SUMMARY OF INVENTION

### Technical Problem

However, in a case where the photonic-crystal surface-emitting laser element was mounted on a circuit board or a heat sink, there was a problem in that stress was generated in the photonic-crystal surface-emitting laser element, the oscillation threshold current increased, and therefore, the light emission efficiency decreased and the oscillation mode was unstable.

In particular, in a case of performing a continuous current conduction drive (CW drive), there was a problem in that the drive current increased due to strain inherent in the photonic-crystal surface-emitting laser element, the power conversion efficiency decreased while the amount of heat generation increases, and therefore, a sufficient output could not be obtained and the oscillation mode was unstable.

An object of the present invention is to provide a photonic-crystal surface-emitting laser device in which an increase in oscillation threshold current and drive current of a photonic-crystal surface-emitting laser element is suppressed and which has a stable oscillation mode and excellent beam quality.

### Solution to Problem

A surface-emitting laser device according to a first embodiment of the present invention includes:
a surface-emitting laser element;
a mounting substrate on which the surface-emitting laser element is placed and which is electrically connected to the surface-emitting laser element; and
an element-bonding member made of a conductive bonding material that bonds the surface-emitting laser element and the mounting substrate and mitigates strain in the surface-emitting laser element due to the mounting substrate, in which the surface-emitting laser element includes:
a translucent element substrate,
a first semiconductor layer that is provided on the element substrate,
an active layer that is provided on the first semiconductor layer,
a second semiconductor layer of a conductive type opposite to the first semiconductor layer, provided on the active layer,
an air-hole layer that is a photonic crystal layer included in the first semiconductor layer or the second semiconductor layer and including an air hole disposed with a two-dimensional periodicity in a plane parallel to the active layer, and
a light reflection layer that is provided on the second semiconductor layer and has a reflection surface, and
a light emission surface is provided on a surface side opposite to a surface of the element substrate, on which the first semiconductor layer is provided.

### BRIEF DESCRIPTION OF DRAWINGS

FIG. 1 is a cross-sectional view illustrating a cross section of a surface-emitting laser device of a first embodiment.

FIG. 2A is a cross-sectional view schematically illustrating an example of a structure of a PCSEL element of the first embodiment.

FIG. 2B is an enlarged cross-sectional view schematically illustrating the arrangement of the air hole pairs in the photonic crystal layer illustrated in FIG. 2A

FIG. 3A is a plan view schematically illustrating an upper surface of the PCSEL element illustrated in FIG. 2A.

FIG. 3B is a cross-sectional view schematically illustrating a cross section of the photonic crystal layer in a plane parallel to an n-side guide layer.

FIG. 3C is a plan view schematically illustrating a lower surface of the PCSEL element.

FIG. 4 is a view schematically illustrating a cross section of the formed photonic crystal layer, perpendicular to a crystal layer.

FIG. 5A is a surface SEM image illustrating main holes 14H1 and secondary holes 14H2 bored in a GaN layer (n-side guide layer) in a case of forming a photonic crystal layer.

FIG. 5B is a view illustrating a surface SEM image of the formed main air holes 14K1 and secondary air holes 14K2.

FIG. 6 is a cross-sectional view schematically illustrating a cross section of the arrangement of the main air hole 14K1 and the secondary air hole 14K2 in the depth direction of the double lattice structure.

FIG. 7 illustrates current-output characteristics of a PCSEL element before and after the mounting in a surface-emitting laser device 5 of Example 1 (EMB1).

FIG. 8 is a graph illustrating oscillation spectra before and after the mounting in a case where a current of 3.0 A is applied to a PCSEL element in the surface-emitting laser device of Example 1.

FIG. 9A is a view illustrating a photonic band of a PCSEL element.

FIG. 9B is a view illustrating a Γ point spectrum before oscillation (lower part) and a spectrum immediately after oscillation (upper part).

FIG. 10A is a view illustrating an FFP before mounting in a case where a current of 3.0 A is applied to a PCSEL element in the surface-emitting laser device of Example 1.

FIG. 10B is a view illustrating an FFP after mounting in a case where a current of 3.0 A is applied to the PCSEL element in the surface-emitting laser device of Example 1.

FIG. 11 is a view illustrating current-output characteristics of a PCSEL element before and after the mounting in a surface-emitting laser device of Comparative Example 1 (CMP1).

FIG. 12 illustrates oscillation spectra before and after the mounting in a case where a current of 3.0 A is applied to the PCSEL element in the surface-emitting laser device of Comparative Example 1.

FIG. 13A is a view illustrating an FFP before mounting in a case where a current of 3.0 A is applied to a PCSEL element in the surface-emitting laser device of Comparative Example 1.

FIG. 13B is a view illustrating an FFP after mounting in a case where a current of 3.0 A is applied to a PCSEL element in the surface-emitting laser device of Comparative Example 1.

FIG. 14 is a view illustrating a base material which is a graphite laminated plate.

FIG. 15 is a graph illustrating current-output characteristics of a PCSEL element before and after the mounting in a surface-emitting laser device of Example 2 (EMB2).

FIG. 16 illustrates oscillation spectra before and after the mounting in a case where a current of 3.0 A is applied to the PCSEL element in the surface-emitting laser device of Example 2.

FIG. 17A is a view illustrating an FFP before mounting in a case where a current of 3.0 A is applied to a PCSEL element in the surface-emitting laser device of Example 2.

FIG. 17B is a view illustrating an FFP after mounting in a case where a current of 3.0 A is applied to the PCSEL element in the surface-emitting laser device of Example 2.

FIG. 18A is a table illustrating a base material of the mounting substrate, bonding conditions, and oscillation characteristics of the PCSEL element before and after the mounting, of the surface-emitting laser device in Example 1.

FIG. 18B is a table illustrating a base material of the mounting substrate, bonding conditions, and oscillation characteristics of the PCSEL element before and after the mounting, of the surface-emitting laser device in Example 2.

FIG. 18C is a table illustrating a base material of the mounting substrate, bonding conditions, and oscillation characteristics of the PCSEL element before and after the mounting, of the surface-emitting laser device in Comparative Example 1.

FIG. 19 is a table illustrating physical property values of materials used in Examples 1 and 2 and Comparative Example 1.

FIG. 20 is a graph plotting a change rate in a threshold current with respect to a strain amount ε applied to a PCSEL element by mounting on a mounting substrate (base material).

FIG. 21 is a view illustrating stresses σ applied to GaN at the time of mounting on a mounting substrate in cases where GaN, diamond, and three-layer graphite are used as a base material of a mounting substrate.

### DESCRIPTION OF EMBODIMENTS

Hereinafter, preferred embodiments of the present invention will be described, but these embodiments may be appropriately modified and combined. In addition, in the following description and the accompanying drawings, substantially the same or equivalent parts will be described with the same reference numerals.

### First Embodiment

### 1. Structure of Photonic-Crystal Surface-Emitting Laser Device

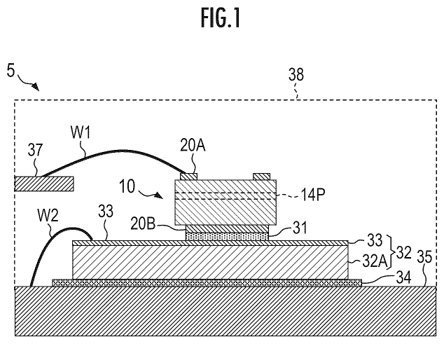

FIG. 1 is a cross-sectional view illustrating a cross section of a surface-emitting laser device 5 of the present embodiment. The surface-emitting laser device 5 includes a photonic-crystal surface-emitting laser (PCSEL) element 10, an element-bonding member 31, a mounting substrate 32, a substrate-bonding member 34, a heat sink 35, and a housing 38.

The photonic-crystal surface-emitting laser element (hereinafter also referred to as the PCSEL element) 10 has a photonic crystal layer 14P inside. In addition, the PCSEL element 10 has a first electrode 20A (n electrode) and a second electrode 20B (p electrode).

The PCSEL element 10 is mounted on the mounting substrate 32 by being bonded to the mounting substrate 32 by the element-bonding member 31. More specifically, the second electrode 20B of the PCSEL element 10 is bonded to and electrically connected to a wiring electrode 33, which is a conductive layer on the mounting substrate 32, by the element-bonding member 31.

The mounting substrate 32 is bonded to the heat sink 35 by the substrate-bonding member 34. In addition, the wiring electrode 33 of the mounting substrate 32 is electrically connected to the heat sink 35 by a bonding wire W2.

Furthermore, in the present embodiment, the heat sink 35 is a conductor and functions as an anode electrode of the surface-emitting laser device 5. However, the connection form is not limited thereto. For example, the wiring electrode 33 may be configured to be connected to an anode electrode (second terminal, not illustrated) of the surface-emitting laser device 5.

In addition, the first electrode 20A of the PCSEL element 10 is electrically connected to the first terminal 37 (cathode electrode) of the surface-emitting laser device 5 by the bonding wire W2. Therefore, the PCSEL element 10 emits light by applying a voltage between the first terminal 37 and the second terminal.

The above-described components are accommodated in the housing 38 to constitute the surface-emitting laser device 5.

### (Mounting Substrate)

A diamond substrate having a thickness of 500 μm and excellent heat dissipation properties was used as a base material 32A of the mounting substrate 32 (sub-mount). As other examples of the base material 32A of the mounting substrate 32, aluminum nitride (AlN), silicon carbide (SIC), alumina (Al₂O₃), copper-aluminum nitride-copper (Cu—AlN—Cu), copper-tungsten (CuW), GaN, graphite, or the like may be used.

Furthermore, in the present embodiment, a metal film coating layer made of nickel/palladium/gold (Ni/Pd/Au) was used as the wiring electrode 33 of the mounting substrate 32.

### (Element-Bonding Member)

As the element-bonding member 31, a paste material (MAX102, manufactured by NIHON HANDA Co., Ltd.) in which silver fine particles (silver nanoparticles) were mixed in an organic solvent or a paste material (AuRoFUSE, manufactured by Tanaka Kikinzoku Kogyo K. K.) in which gold fine particles (gold nanoparticles) were mixed was used. The paste material can be sintered at 200° C., and the PCSEL element 10 and the mounting substrate 32 can be bonded to each other at a sufficiently lower temperature, as compared with the sintering temperature of 320° C. of the gold-tin alloy (AuSn) used as a bonding material in the related art. That is, the thermal strain can be suppressed to bond the PCSEL element 10.

Specifically, the bonding material was applied to the mounting substrate 32, and then the PCSEL element 10 was mounted under load with a force of approximately 1.5 kfg/cm². The mounting substrate 32 on which the PCSEL element 10 was mounted under load was introduced into a sintering oven, heated to 200° C. in an N2 atmosphere, and sintered for 1 hour.

Furthermore, the sintering temperature may be in a range of 80° C. to 320° C. In a case where the temperature is too low, the fine metal particles will not be sintered, whereas in a case where the temperature is too high, the element characteristics will deteriorate. For example, the I-V characteristics are impaired. In addition, the sintering time may be a time during which the organic solvent included in the element-bonding member 31 is vaporized during sintering, and may be, for example, 2 minutes to 8 hours.

Furthermore, in the present Examples, a paste material in which silver nanoparticles or gold nanoparticles have been mixed is used, but a paste material including at least one kind of fine metal particles (nanoparticles) such as gold (Au), silver (Ag), and copper (Cu) may be used. It is preferable to use the fine metal particles of the order of nanometers in the element-bonding member 31 from the viewpoint that the bonding temperature of the PCSEL element 10 to the mounting substrate 32 can be lowered.

As described above, in a case of fine metal particles in which contact portions between the particles are bonded (necked) by sintering at a low temperature and which have high conductivity and high heat dissipation properties, fine particles other than the above-described metal nanoparticles can also be used.

In addition, it is preferable that the element-bonding member 31 has a Young's modulus smaller than a Young's modulus of the mounting substrate 32. The Young's modulus of the element-bonding member 31 is more preferably 100 or less, and still more preferably 70 or less.

In addition, in a case where the PCSEL element 10 is mounted on the mounting substrate 32, a bonding process at normal temperature may be used. For example, the bonding surfaces of the second electrode 20B and the wiring electrode 33 of the PCSEL element 10 are activated by Ar and H2 plasma, and then the second electrode 20B and the wiring electrode 33 are pressurized at normal temperature. Accordingly, the PCSEL element 10 and the mounting substrate 32 can be bonded to each other.

### (Substrate-Bonding Member)

An indium alloy (content ratio: In 0.52-Sn 0.48) was used for the substrate-bonding member 34. Specifically, the substrate-bonding material was applied onto the heat sink 35, the heat sink 35 was heated to 120° C. to soften the bonding member, and the mounting substrate 32 on which the PCSEL element 10 was mounted was pressurized to bond the heat sink 35 and the mounting substrate 32 to each other.

### (Heat Sink)

The heat sink 35 is formed of copper (Cu) having excellent electrical conductivity and excellent thermal conductivity. A Peltier cooling device is disposed on a back surface of the heat sink 35 (the surface opposite to a bonding surface with the mounting substrate 32), and the back surface is kept at a predetermined constant temperature.

### (Sealing Gas)

The surface-emitting laser device 5 was sealed by a housing 38 and dry nitrogen was used as an internal sealing gas. As the sealing gas, a nitrogen-oxygen mixed gas, dry air, or the like can be used.

In a case where the wavelength of the radiated light of the PCSEL element 10 is shorter than 420 nm, the generation of a carbide derived from the residual organic substance can be suppressed by mixing a few percent of oxygen.

### 2. Structure of Photonic-Crystal Surface-Emitting Laser Element

The photonic-crystal surface-emitting laser element (PCSEL element) includes a resonator layer in a direction parallel to a semiconductor light-emitting structure layer (n-side guide layer, a light-emitting layer, and a p-side guide layer) constituting a light-emitting element, and is an element that radiates coherent light in a direction orthogonal to the resonator layer.

That is, in the PCSEL element, light waves propagating in a plane parallel to a photonic crystal layer are diffracted due to a diffraction effect of the photonic crystal to form a two-dimensional resonance mode and are also diffracted in a direction perpendicular to the parallel plane. That is, in the PCSEL element, the light extraction direction is a direction which is perpendicular to the resonance direction (within a plane parallel to the photonic crystal layer).

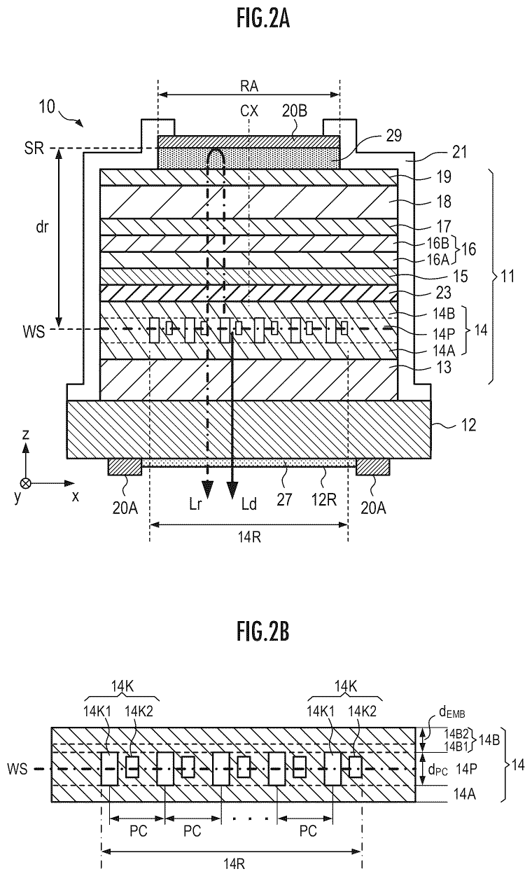

FIG. 2A is a cross-sectional view schematically illustrating an example of a structure of a photonic-crystal surface-emitting laser element (a PCSEL element) 10 according to the embodiment of the present invention. In addition, FIG. 2B is an enlarged cross-sectional view schematically illustrating a photonic crystal layer 14P in FIG. 2A and an air hole pair 14K arranged in the photonic crystal layer 14P.

As illustrated in FIG. 2A, a semiconductor structure layer 11 is formed on a translucent element substrate 12. Furthermore, semiconductor layers are laminated perpendicularly to a central axis CX of the semiconductor structure layer 11.

In addition, the semiconductor structure layer 11 is made of a hexagonal nitride semiconductor. In the present embodiment, the semiconductor structure layer 11 is, for example, made of a GaN-based semiconductor.

More specifically, the semiconductor structure layer 11 made of a plurality of semiconductor layers, that is, an n-cladding layer (a first cladding layer of a first conductivity type) 13, an n-side guide layer (first guide layer) 14 that is a guide layer provided on the n-side, a light distribution adjustment layer 23, an active layer (ACT) 15, a p-side guide layer (second guide layer) 16 that is a guide layer provided on the p-side, an electron blocking layer (EBL) 17, a p-cladding layer (a second cladding layer of a second conductivity type) 18, and a p-contact layer 19 are formed on the element substrate 12 in this order.

Furthermore, although the case where the first conductivity type is an n-type and the second conductivity type that is a conductivity type opposite to the first conductivity type is a p-type will be described, the first conductivity type and the second conductivity type may be a p-type and an n-type, respectively.

The element substrate 12 is a hexagonal GaN single crystal and has a high transmittance of light radiated from the active layer 15. More specifically, the element substrate 12 is a hexagonal GaN single crystal substrate of which a main surface (crystal growth surface) is a +c-plane, which is a {0001} plane in which Ga atoms are arranged on the outermost surface. A back surface (light emission surface) is a −c plane, which is a (000-1) plane in which N atoms are arranged on the outermost surface. The −c plane is resistant to oxidation or the like and is therefore suitable as a light emission surface.

The element substrate 12 is not limited thereto, but a so-called just substrate, or, for example, a substrate of which a main surface is offset to about 1° in the m-axis direction is preferably used. For example, the substrate that is offset to about 0.3 to 0.7° in the m-axis direction can obtain mirror-finish growth under a wide range of growth conditions.

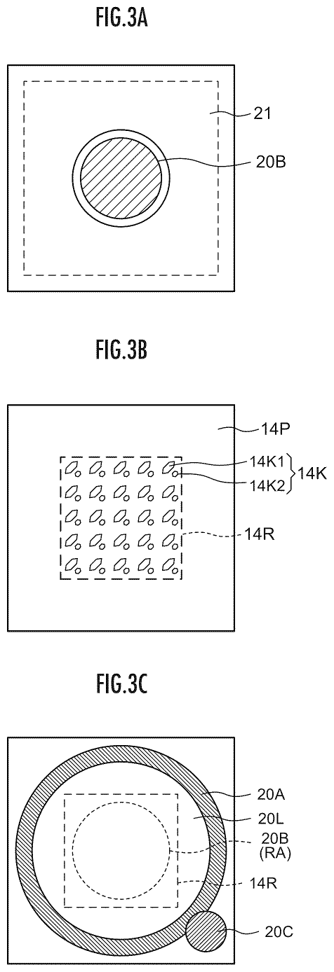

A substrate surface (back surface or a light emission surface) on which a light emission region 20L facing the main surface (FIG. 3C) is provided is the “−c” plane, which is the (000-1) plane on which N atoms are arranged on the outermost surface. The −c-plane is resistant to oxidation or the like, and is therefore suitable as a light extraction surface.

Hereinafter, configurations such as a composition and a layer thickness of each of the semiconductor layers will be described, but these configurations are merely examples and can be appropriately modified and applied.

The n-cladding layer 13 is, for example, an n-Al_{0.04}Ga_{0.96}N layer having an Al composition of 4% and a layer thickness of 2 μm. The aluminum (Al) composition ratio is based on a composition in which a refractive index is smaller than that of a layer (that is, the n-side guide layer 14) adjacent to the active layer 15 side.

The n-side guide layer 14 is made of a lower guide layer 14A, a photonic crystal layer (PC layer) 14P that is an air-hole layer, and an embedded layer 14B. As illustrated in FIG. 2B, the photonic crystal layer 14P has a layer thickness dec and the embedded layer 14B has a layer thickness d_{EMB}. For example, the layer thickness dec of the photonic crystal layer 14P is 40 to 180 nm.

Furthermore, in the present specification, the photonic crystal layer 14P refers to a layer portion from the upper end to the lower end of the air holes in the n-side guide layer 14 (refer to FIG. 2B). Therefore, the layer thickness d_{PC} of the photonic crystal layer 14P is equal to the height of the air holes.

The lower guide layer 14A is, for example, n-GaN having a layer thickness of 100 to 400 nm. The photonic crystal layer 14P is n-GaN having a layer thickness (or a depth of the air holes 14K) of 40 to 180 nm.

The embedded layer 14B is made of n-GaN, n-InGaN, or undoped GaN or undoped InGaN. Alternatively, the embedded layer 14B may be a layer in which these semiconductor layers are laminated. The embedded layer 14B has, for example, a layer thickness d_{EMB} of 50 to 150 nm. Furthermore, the embedded layer 14B is made of a first embedded layer 14B1 and a second embedded layer 14B2.

The light distribution adjustment layer 23 formed on the embedded layer 14B is an undoped In_{0.03}Ga_{0.97}N layer, and has, for example, a layer thickness of 50 nm.

Furthermore, the n-side semiconductor layer including the n-side guide layer 14 and the light distribution adjustment layer 23 is also referred to as a first semiconductor layer, but the light distribution adjustment layer 23 may not be provided.

The active layer 15 which is a light-emitting layer is, for example, a multiple quantum well (MQW) layer having two quantum well layers. A barrier layer and the quantum well layer of the MQW are GaN (layer thickness: 6.0 nm) and InGaN (layer thickness: 4.0 nm), respectively. In addition, a center emission wavelength of the active layer 15 is 440 nm.

Furthermore, it is preferable that the active layer 15 is disposed 180 nm or less (that is, within the air-hole period PC) from the photonic crystal layer 14P. In this case, a high resonance effect is obtained by the photonic crystal layer 14P.

The p-side guide layer 16 is made of a p-side guide layer (1) 16A which is an undoped In_{0.02}Ga_{0.98}N layer (layer thickness 70 nm) and a p-side guide layer (2) 16B which is an undoped GaN layer (layer thickness 180 nm).

The p-side guide layer 16 is an undoped layer in consideration of light absorption by a dopant (Mg: magnesium or the like), but may be doped in order to obtain good electrical conductivity. In addition, in order to adjust an electric field distribution in an oscillation operation mode, the In composition and the layer thickness of the p-side guide layer (1) 16A can be appropriately selected.

The electron blocking layer (EBL) 17 is a p-type Al_{0.2}Ga_{0.8}N layer doped with magnesium (Mg), and has, for example, a layer thickness of 15 nm.

The p-cladding layer 18 is an Mg-doped p-Al_{0.06}Ga_{0.94}N layer, and has, for example, a layer thickness of 600 nm. The Al composition of the p-cladding layer 18 is preferably selected such that a refractive index is smaller than that of the p-side guide layer 16. The p-cladding layer 18 functions as a first p-cladding layer.

In addition, the p-contact layer 19 is an Mg-doped p-GaN layer and has, for example, a layer thickness of 20 nm. A carrier density of the p-contact layer 19 is set to a concentration that allows an ohmic junction to be formed with a translucent electrode 29, which is a translucent conductor layer provided on the surface of the p-contact layer 19. Instead of p-type GaN, p-type or undoped InGaN may be used. Alternatively, a layer in which a GaN layer and an InGaN layer are laminated may be used.

Furthermore, the layer made of the p-side guide layer 16, the electron blocking layer 17, the p-cladding layer 18, and the p-contact layer 19 is also referred to as a second semiconductor layer.

Furthermore, in the present specification, an “n-side” and a “p-side” do not necessarily mean having an n-type and a p-type. For example, the n-side guide layer means a guide layer provided closer to the n-side than the active layer, and may be an undoped layer (or an i layer).

In addition, the n-cladding layer 13 may include a plurality of layers instead of a single layer, and in this case, all the layers do not need to be n layers (n-doped layers), and may include an undoped layer (i layer). The same also applies to the guide layer 16 and the p-cladding layer 18.

Furthermore, it is not necessary to provide all of the semiconductor layers described above, and there may be a configuration in which a first semiconductor layer of a first conductivity type, a second semiconductor layer of a second conductivity type, and an active layer (light-emitting layer) interposed between these layers are provided.

In addition, in the present embodiment, a case where the photonic crystal layer 14P (air-hole layer) is provided in the first semiconductor layer (n-type semiconductor layer) has been described, but a configuration in which the photonic crystal layer is provided in the second semiconductor layer (p-type semiconductor layer) may be adopted.

The translucent electrode 29 (anode) that makes ohmic contact with the p-contact layer 19 is provided on the p-contact layer 19. Furthermore, the translucent electrode 29 functions not only as an electrode layer but also as a second p-cladding layer.

The translucent electrode 29 has a circular shape with a diameter RA centered on the central axis CX of the semiconductor structure layer 11. Specifically, the translucent electrode 29 has, for example, a diameter of RA=300 μm in a top view (that is, in a case of being viewed from a direction perpendicular to the semiconductor structure layer 11).

The translucent electrode 29 is formed of a translucent conductor and is, for example, formed of indium tin oxide (ITO). Furthermore, the translucent electrode 29 is not limited to ITO, and a translucent conductor such as zinc tin oxide (ZTO), GZO (ZnO:Ga), or AZO (ZnO:Al) can be used.

On the translucent electrode 29, an Ag/Au layer made of a silver (Ag) layer and a gold (Au) layer formed on the Ag layer is formed as a p-electrode 20B (second electrode). That is, the p-electrode 20B functions as a light reflection layer, and the interface between the translucent electrode 29 and the Ag layer of the p-electrode 20B is a reflection surface SR. Furthermore, the reflection surface SR is provided in parallel with the photonic crystal layer 14P.

Furthermore, as the p-electrode 20B, Pd, Al, an Al alloy, a dielectric distributed bragg reflector (DBR), or the like can also be used. In addition, a pad electrode or the like may be provided on the p-electrode 20B.

The side surface and the upper surface of the semiconductor structure layer 11 and the side surfaces of the translucent electrode 29 and the p-electrode 20B are covered with an insulating film 21 such as SiO₂. In addition, the insulating film 21 is formed to overlap the p-electrode 20B and cover the edge of the upper surface of the p-electrode 20B.

The insulating film 21 also functions as a protective film and protects the crystal layer including aluminum (Al) constituting the PCSEL element 10 from a corrosive gas and the like. In addition, the insulating film 21 prevents short circuits or the like due to deposits and creeping-up of a solder during mounting, and contributes to improvement of reliability and yield. A material of the insulating film 21 is not limited to SiO₂, and ZrO₂, HfO₂, TiO₂, Al₂O₃, SiNₓ, Si, and the like may be selected.

An annular cathode electrode 20A (first electrode) is formed on the back surface of the element substrate 12 (refer to FIG. 3C). In addition, an anti-reflection (AR) coating layer 27 is formed inside the cathode electrode 20A.

The cathode electrode 20A is made of Ti/Au and is in ohmic contact with the element substrate 12. In addition to Ti/Au, the electrode material can be selected from Ti/Al, Ti/Rh, Ti/Al/Pt/Au, Ti/Pt/Au, or the like.

The light radiated from the active layer 15 is diffracted by the photonic crystal layer (PC layer) 14P. The light (direct diffracted light Ld: first diffracted light) diffracted by the photonic crystal layer 14P and directly emitted from the photonic crystal layer 14P, and light (reflected diffracted light Lr: second diffracted light) emitted due to diffraction of the photonic crystal layer 14P and reflected by a light reflection layer 32 are emitted to the outside from the light emission region 20L (FIG. 3C) of a back surface (emission surface) 12R of the element substrate 12.

FIG. 3A is a plan view schematically illustrating the upper surface of the PCSEL element 10. In addition, FIG. 3B is a cross-sectional view schematically illustrating a cross section of the photonic crystal layer 14P in a plane parallel to the n-side guide layer 14, and FIG. 3C is a plan view schematically illustrating a lower surface of the PCSEL element 10.

As illustrated in FIG. 3B, in the photonic crystal layer 14P, the air holes 14K are provided, for example, by being arranged periodically in a rectangular air hole formation region 14R.

As illustrated in FIG. 3C, an anode region RA is formed to be included in the air hole formation region 14R.

The cathode electrode 20A is provided as a ring-shaped electrode outside the p-electrode 20B not to overlap the p-electrode 20B in a case where viewed in a vertical direction with respect to the photonic crystal layer 14P.

The region inside the cathode electrode 20A is a light emission region 20L. In addition, a bonding pad 20C that is electrically connected to the cathode electrode 20A and connected to a wire for supplying power from the outside is provided.

### (Structure of Photonic Crystal Layer)

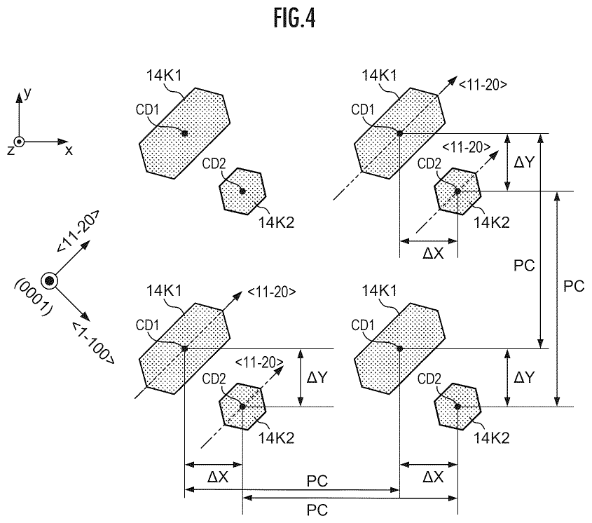

FIG. 4 is a view schematically illustrating a cross section of the formed photonic crystal layer 14P, perpendicular to a crystal layer. The photonic crystal layer 14P of the present embodiment is a double lattice photonic crystal layer in which an air hole pair 14K made of a main air hole 14K1 and a secondary air hole 14K2 is disposed at each of the square lattice points. Furthermore, in a case where the main air hole 14K1 and the secondary air hole 14K2 are not particularly distinguished from each other, they may be collectively referred to as the air hole 14K.

More specifically, centroids CD1 of the main air holes 14K1 are arranged in a square lattice shape with the period PC in two directions (x direction and y direction) that are orthogonal to each other. In addition, centroids CD2 of the secondary air holes 14K2 are also similarly arranged in a square lattice shape with the air-hole period PC in the x direction and the y direction.

The major axes of the main air hole 14K1 and the secondary air hole 14K2 are parallel to a <11-20> direction of the crystal orientation, and the minor axes of the main air hole 14K1 and the secondary air hole 14K2 are parallel to a <1-100> direction.

In addition, the centroid CD2 of the secondary air hole 14K2 is separated from the centroid CD1 of the main air hole 14K1 by Δx and Δy. Here, Δx=Δy was set. That is, the centroid CD2 of the secondary air hole 14K2 is separated from the centroid CD1 of the main air hole 14K1 in the <1-100> direction.

Specifically, the period PC was set to 176.8 nm, and the distances Δx and Δy between the centroids of the main air holes 14K1 and the secondary air holes 14K2 were set to satisfy Δx=Δy=0.46 PC.

FIG. SA is a surface scanning electron microscope (SEM) image illustrating the main holes 14H1 and the secondary holes 14H2 bored in a GaN layer (n-side guide layer 14) in a case of forming a photonic crystal layer 14P.

The main hole 14H1 and the secondary hole 14H2 have an elongated columnar shape having a direction perpendicular to the crystal layer as a central axis. Furthermore, in a case where the main hole 14H1 and the secondary hole 14H2 are not particularly distinguished from each other, they may be collectively referred to as the hole 14H.

The main hole 14H1 and the secondary hole 14H2 are embedded and blocked by the mass transport, and the first embedded layer 14B1 is formed. Subsequently, the main air hole 14K1 and the secondary air hole 14K2 are formed by being embedded by the second embedded layer 14B2.

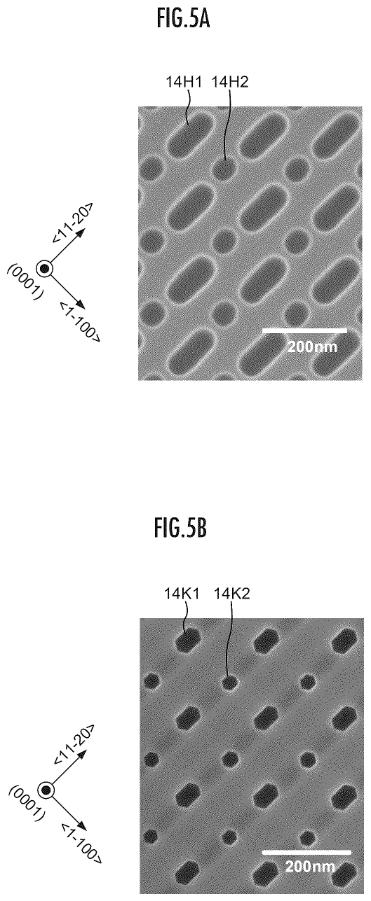

FIG. 5B is a view illustrating a surface SEM image of the formed main air holes 14K1 and secondary air holes 14K2. In a case where the holes 14H are embedded in group III nitride, the shapes of the holes 14H are deformed into shapes configured with thermally stable surfaces by mass transport, and air holes 14K are formed.

That is, in a +c-plane substrate, the shape of the inner side surface of the hole 14H changes to a (1-100) plane (that is, an m plane). That is, the shape changes from an oblong columnar shape to an air hole 14K having a long hexagonal columnar shape, whose side surfaces are configured with the m-plane.

The formed main air hole 14K1 had a long hexagonal columnar shape with a major axis of 72.5 nm and a minor axis of 43.5 nm, with a major axis/minor axis ratio of 1.67. The secondary air hole 14K2 had a major axis of 44.6 nm and a minor axis of 38.3 nm, with a major axis/minor axis ratio of 1.16, and had a long hexagonal columnar shape closer to a regular hexagonal columnar than the main air hole 14K1.

Moreover, it was confirmed that the distances Δx and Δy between the centroids of the main air hole 14K1 and the secondary air hole 14K2 were 81.6 nm (Δx=Δy=0.46 PC), and had not changed since before the embedding. In addition, it was also confirmed that the major axes of the main air hole 14K1 and the secondary air hole 14K2 were parallel to the <11-20> axis (that is, the a-axis).

In addition, air hole filling rates (filling factors) FF1 and FF2 of the main air hole 14K1 and the secondary air hole 14K2 were calculated to be FF1=8.8% and FF2=4.2% The air hole filling rate herein means a proportion of the area occupied by each air hole per unit area in a two-dimensional regular array. Specifically, in a case where the areas of the main air hole 14K1 and the secondary air hole 14K2 in the photonic crystal layer 14P are set to S1 and S2, respectively, the air hole filling rates FF1 and FF2 of the main air hole 14K1 and the secondary air hole 14K2 are given by the following expressions.

FF1=S1/PC², FF2=S2/PC²

(Separation Distance between Diffraction Surface and Reflection Surface)

In the PCSEL element 10 of the present embodiment, a separation distance dr between a diffraction surface WS and a reflection surface SR is adjusted (refer to FIG. 2A). This is configured to suppress losses due to diffraction in the vertical direction in the photonic crystal layer 14P by controlling an interference between a direct diffracted light Ld that is directly emitted from the diffraction surface WS and a reflected diffracted light Lr that is diffracted in the +z direction, reflected by the reflection surface SR, and emitted.

Furthermore, for example, from Non Patent Literature 1, the coupled wave theory can be used to calculate the position of the diffraction surface WS (or the wave source), which is the diffraction position of the diffracted wave by the photonic crystal layer 14P, and the radiated wave that is diffracted and radiated in the vertical direction of the photonic crystal layer 14P. Therefore, the separation distance dr between the diffraction surface WS and the reflection surface SR can be calculated using the position of the diffraction surface WS.

The position of the diffraction surface WS in the photonic crystal layer 14P of the PCSEL element 10 of the present embodiment was estimated by the method described in Non Patent Literature 1. That is, it was estimated that the diffraction surface WS was located about 7 nm closer to the active layer 15 side than the centroid of the photonic crystal layer 14P.

In a case where a phase difference between the first diffracted light (direct diffracted light Ld) diffracted by the diffraction surface WS and the second diffracted light (reflected diffracted light Lr) diffracted by the diffraction surface WS and reflected by the reflection surface SR is denoted by θ (deg), a wavelength of the first diffracted light is denoted by 2, an average refractive index of the crystal layer from the diffraction surface WS to the reflection surface SR is denoted by nave, and an integer of 0 or more is denoted by m, a separation distance dr is represented by Expression (1)

dr={(θ/360)+0.5+m}λ/2nₐᵥₑ (1).

In addition, under the condition that the phase difference θ satisfies Expression (2), the light intensities of the interference light of the direct diffracted light Ld and the reflected diffracted light Lr are smaller than the light intensity of the direct diffracted light Ld.

cosθ<0 (2).

In other words, this means that emitted light is weakened by the interference between the direct diffracted light Ld and the reflected diffracted light Lr, and the radiation loss (loss in the vertical direction) is reduced.

Furthermore, in order to prevent interference (mutual weakening) from occurring inside the photonic crystal layer 14P, the photonic crystal layer 14P preferably has a thickness (dc) such that the optical path length of the photonic crystal layer 14P is less than one wavelength.

Therefore, it is possible to obtain a two-dimensional photonic-crystal surface-emitting laser element (PCSEL element) capable of driving with a low current.

### (Arrangement of Main Air Holes and Secondary Air Holes of Double Lattice Structure)

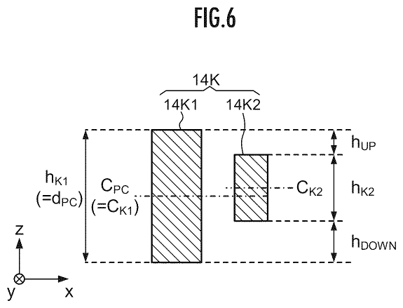

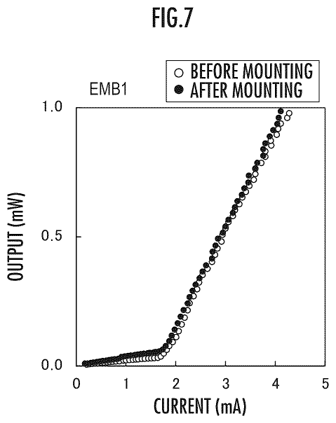

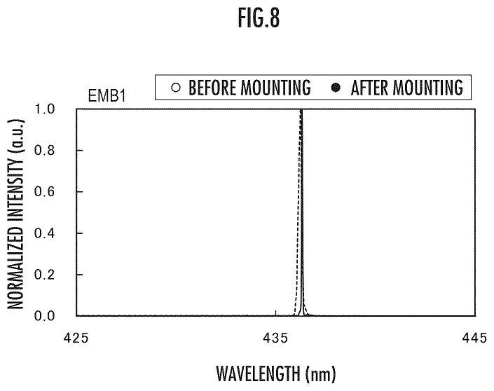

FIG. 6 is a cross-sectional view schematically illustrating cross sections of the main air hole 14K1 and the secondary air hole 14K2 in the depth direction of the double lattice structure. Here, the main air hole 14K1 and the secondary air hole 14K2 have different air hole heights (depths). That is, the height of the main air hole 14K1 is h_{K1} and is equal to the thickness of the photonic crystal layer 14P (h_{K1}=d_{PC}). In addition, the height of the secondary air hole 14K2 is h_{K2}.

More specifically, the lower end of the main air hole 14K1 is located deeper than the lower end of the secondary air hole 14K2, that is, in the −z direction. The difference between the lower ends of the main air hole 14K1 and the secondary air hole 14K2 is h_{DOWN}. In addition, the upper end of the secondary air hole 14K2 is deeper than the upper end of the main air hole 14K1, and the difference therebetween is h_{UP}.

Here, the difference h_{UP} between the upper ends is smaller than the difference h_{DOWN} between the lower ends, and the centroid C_{PC}(=C_{K2}) of the secondary air hole 14K2 in the depth direction (−z direction) is located closer to the side of the active layer 15 than the centroid C_{K1} of the main air hole 14K1.

In a nitride-based PCSEL element, in a case where holes of different sizes are formed simultaneously by a method such as dry etching and the holes are embedded to form the main air hole 14K1 and the secondary air hole 14K2, the side surfaces of the formed main air hole 14K1 and secondary air hole 14K2 each have a hexagonal columnar structure with m-plane sides. Therefore, the size relationship between the main air hole 14K1 and the secondary air hole 14K2 at any z-direction position in the photonic crystal layer 14P is the same as the size relationship between the holes before embedding.

Furthermore, in the photonic crystal layer 14P of the nitride-based PCSEL element, the lower end of the main air hole 14K1 having a large air hole filling rate FF is located closer to the side of the lower end of the photonic crystal layer 14P than the secondary air hole 14K2, that is, the main air hole 14K1 is deeper than the secondary air hole 14K2. In addition, the upper end of the secondary air hole 14K2 is formed deeper than the upper end of the main air hole 14K1 by the embedding growth.

Furthermore, in a case where the active layer 15 is formed after the photonic crystal layer 14P is formed, that is, in a case where the photonic crystal layer 14P is provided on the −z direction side of the active layer 15, the relationship FF1>FF2 is always satisfied. That is, in a nitride-based PCSEL element, even in the case of a double lattice structure, the wave source (diffraction surface) WS is always located at a position, for example, about 1 to 10 nm away from the centroid C_{PC} (that is, the centroid of the main air hole 14K1) in the z direction of the photonic crystal layer 14P toward the active layer 15.

Therefore, there are regions (regions of h_{UP} and h_{DOWN}) in which only the main air hole 14K1 is present in the depth direction (−z direction) and regions (regions of h_{K2}) in which both the main air hole 14K1 and the secondary air hole 14K2 are present, but the propagating light component diffracted in the vertical direction is larger in the region in which both the main air hole 14K1 and the secondary air hole 14K2 are present. Accordingly the wave source (diffraction surface) WS is also located at a position shifted in the +z direction (towards the active layer 15) from the centroid C_{PC} of the photonic crystal layer 14P.

Furthermore, the air hole has been described, in which the air hole has a hexagonal columnar shape and the cross-sectional area does not change in the depth direction. In a case where either the main air hole 14K1 or the secondary air hole 14K2 has a shape in which the cross-sectional area changes in the depth direction, it is preferable that the centroid of the secondary air hole 14K2 is located closer to the side of the active layer 15 than the centroid of the main air hole 14K1.

### 2. Operation Characteristics

### (1) Example 1

In order to evaluate the effect of the mounting on the mounting substrate 32 on the laser characteristics, the current-output characteristics of the PCSEL element 10 were measured before and after the mounting. In order to eliminate the thermal effect and evaluate the characteristics, the characteristics were evaluated by pulse driving with a pulse width of 100 ns and a repetition frequency of 1 kHz (that is, a duty of 0.01%). In addition, the evaluation was performed at room temperature in any case. That is, in the evaluation of the current-output characteristics, the PCSEL element 10 was driven under pulse conditions in which there was no thermal effect or the thermal effect was negligible.

The current-output characteristics of a PCSEL element 10 before and after the mounting in a surface-emitting laser device 5 of Example 1 (EMB1) having the above-described structure are illustrated in FIG. 7. As illustrated in FIG. 7, in the present Examples, it was found that there was no increase in the threshold current of the PCSEL element 10 due to the mounting on the mounting substrate 32, there was no change in the current-output characteristics, and there was no deterioration in the characteristics.

The oscillation spectra before and after the mounting in a case where a current of 3.0 A is applied to the PCSEL element 10 in the surface-emitting laser device of Example 1 are illustrated in FIG. 8. The oscillation wavelength λ was 436.24 nm before the mounting and was 436.32 nm after the mounting.

Here, the oscillation wavelength λ is given by Expression (3) in a case where m is an integer of 1 or more and the effective refractive index is denoted by n_{eff}.

$$λ = m \times {n}_{eff} \times PC . \qquad ( 3 )$$

In consideration of a fact that the pulse driving has an extremely small duty and is considered to have no thermal effect, it is considered that there is no change in the effective refractive index n_{eff} in the spectral evaluation (FIG. 8). Therefore, it can be seen from Expression (3) that the change amount in the oscillation wavelength λ before and after the mounting is proportional to the change amount in the air-hole period PC of the photonic crystal layer.

In the present Examples, since the oscillation wavelength A is increased before and after the mounting, it is considered that the air-hole period PC is increased and tensile strain is applied to the PCSEL element 10 due to the mounting. The strain amount ε is given by Expression (4).

$$ε = Δ PC / PC = Δλ / λ . \qquad ( 4 )$$

In a case where the strain amount ε in the present Examples was calculated, ε=0.0018% is satisfied.

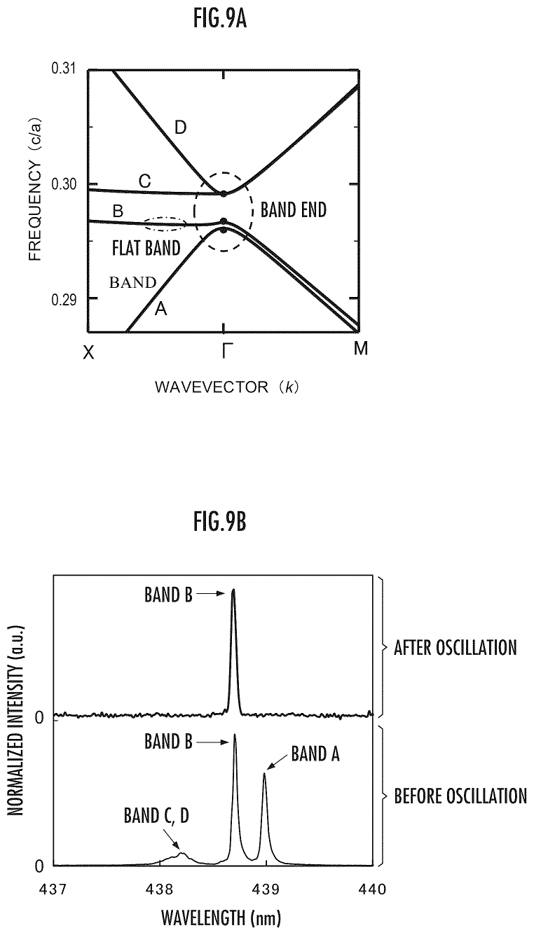

FIG. 9A is a view illustrating a photonic band of a PCSEL element. The PCSEL element performs laser oscillation by utilizing the effect of zero group velocity at the I point of the photonic band (that is, the resonance effect).

In a case of a square lattice photonic crystal, four oscillation modes (A, B, C, and D, respectively, from the low frequency side) are present at the Γ point, and laser oscillation occurs in any of these modes. Each mode can be evaluated by measuring the spectrum at the Γ point before oscillation, that is, the emission spectrum in the direction perpendicular to the surface (normal direction) with respect to the substrate.

FIG. 9B is a view illustrating a Γ point spectrum before oscillation (lower part) and a spectrum immediately after oscillation (upper part). That is, by comparing the Γ point spectrum before oscillation with the spectrum after laser oscillation, it is possible to know which mode the PCSEL element is oscillating in. In the present Examples, the oscillation occurs in the mode B. Furthermore, the modes C and D are degenerate in the spectrum before oscillation.

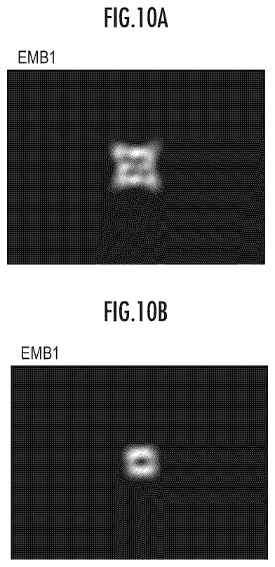

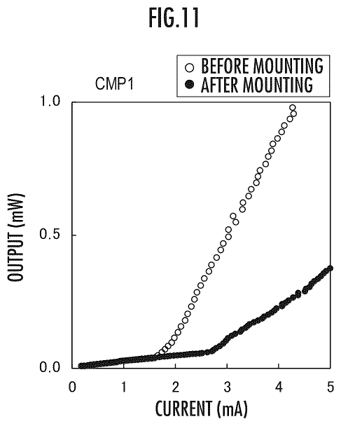

The beam emission patterns (far field patterns: FFPs) before and after the mounting, respectively, in a case where a current of 3.0 A was applied to the PCSEL element 10 in the surface-emitting laser device of Example 1 are illustrated in FIGS. 10A and 10B.

By measuring the spectra before and after oscillation, information regarding the spectrum of FIG. 9B is obtained, and it is found that oscillation occurs in the band edge B mode before and after the mounting. Although a difference is observed in the appearance level of the high-order mode of the band edge B mode before and after the mounting, which is considered to be due to an effect of the strain generated in the PCSEL element due to the mounting.

### (2) Comparative Example 1

The surface-emitting laser device of Comparative Example 1 (CMP1) is different from the surface-emitting laser device 5 of Example 1 in the following points, but is the same as Example 1 in other points.

In the surface-emitting laser device of Comparative Example 1, a fluxless gold-tin alloy (AuSn) was used as the element-bonding member instead of the element-bonding member 31 of Example 1. The melting point of the gold-tin alloy (AuSn) is approximately 280° C. and it is necessary to apply a temperature higher than this temperature in order to perform sintering and mounting.

Specifically, the element-bonding material (AuSn) was applied to the mounting substrate 32, then the mounting substrate 32 was heated to 340° C., and the surface-emitting laser element was mounted under load with a force of approximately 1.5 kg/cm². The surface-emitting laser element was maintained in the loaded state for 10 seconds and then immediately cooled.

In addition, the surface-emitting laser element (PCSEL element) was the same as the PCSEL element 10 in the surface-emitting laser device of Example 1 described above, except that the air-hole period PC of the photonic crystal layer 14P was 177.5 nm.

### (Characteristics Evaluation)

The current-output characteristics of the surface-emitting laser element were measured before and after the mounting in order to evaluate the effect of mounting onto the mounting substrate by the element-bonding member (AuSn) on the laser characteristics. In order to eliminate the thermal effect and evaluate the characteristics, the characteristics were evaluated by pulse driving with a pulse width of 100 ns and a repetition frequency of 1 kHz (that is, a duty is 0.01%), as in the case of Example 1. In addition, the evaluation was performed at room temperature in any case.

The current-output characteristics of the PCSEL element 10 before and after the mounting in the surface-emitting laser device of Comparative Example 1 (CMP1) having the above-described structure are illustrated in FIG. 11. In Comparative Example 1, the current-output characteristics before the mounting were almost the same as those of the surface-emitting laser device 5 of Example 1. However, after the mounting, the threshold current increased, and the current-output characteristics were significantly deteriorated, such as a decrease in slope efficiency.

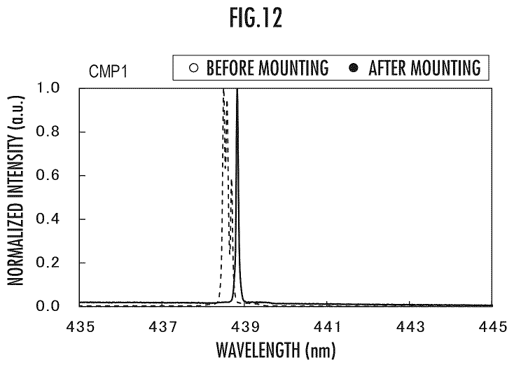

The oscillation spectra before and after the mounting in a case where a current of 3.0 A is applied to the PCSEL element in the surface-emitting laser device of Comparative Example 1 are illustrated in FIG. 12. As described above, the oscillation wavelength λ of Example 1 was 436.24 nm before the mounting and 436.32 nm after the mounting.

In contrast, the oscillation wavelength λ of Comparative Example 1 was 438.48 nm before the mounting and 438.83 nm after the mounting. In addition, the strain amount ε estimated from Expression (4) was 0.079%. That is, it was found that a larger stress (tensile strain) was applied to the PCSEL element, as compared with Example 1.

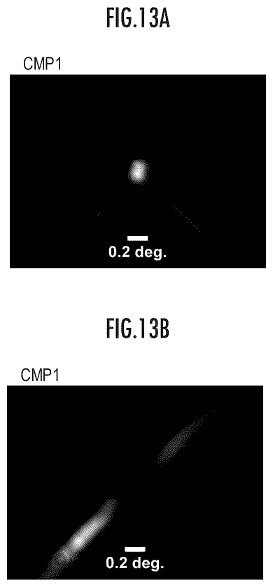

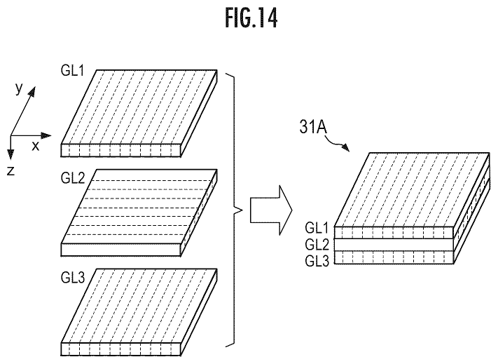

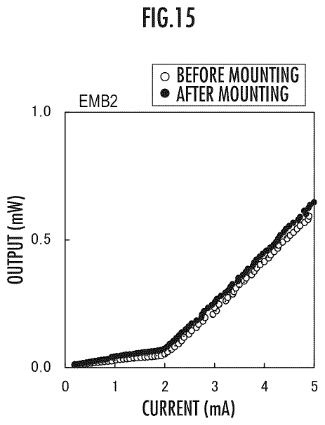

The beam emission patterns (far field patterns: FFPs) before and after the mounting, respectively, in a case where a current of 3.0 A was applied to the PCSEL element in the surface-emitting laser device of Comparative Example 1 are illustrated in FIGS. 13A and 13B. It can be seen from this FFP that before the mounting, the oscillation occurs in the band edge B mode, whereas after the mounting, the oscillation occurs in the flat band mode. Here, the flat band mode refers to a mode extending from the mode B of the photonic band illustrated in FIG. 9A in the Γ-X direction, and refers to an unintended oscillation mode in which laser oscillation occurs from a region other than the Γ point.

By also referring to the oscillation spectrum of FIG. 12, it is considered that in the surface-emitting laser device of Comparative Example 1, the strain amount ε was large, which weakened the two-dimensional resonance effect of light in the photonic crystal layer and the flat band mode which is the one-dimensional oscillation mode appeared. Since the beam quality is significantly deteriorated in the oscillation in the flat band mode, the oscillation in the flat band mode is not preferable even in an application where high light collecting properties are required.

### (3) Example 2

In the surface-emitting laser device 5 of Example 2 (EMB2), a graphite laminated plate was used as the base material 32A of the mounting substrate 32 (sub-mount). In addition, a gold-tin alloy (AuSn) was used for the element-bonding member 34 (the same as in Comparative Example 1). Other points are the same as those in Example 1.

FIG. 14 is a view illustrating a base material 32A which is a graphite laminated plate. The base material 32A is a graphite laminated plate having a three-layer structure formed by laminating three graphite plates GL1, GL2, and GL3 in this order.

The graphite plate GL1 has a thermal conductivity in one in-plane direction (x direction) of 7 W/mK, and a thermal conductivity in directions (y direction and z direction) orthogonal to the x direction of 1,700 W/mK. That is, the graphite plate GL1 is a thermally conductive plate having a large thermal conductivity in a specific direction and a large anisotropy of the thermal conductivity. Specifically, any material having a high thermal conductivity in the a and b axis directions (the y direction and the z direction) with respect to the c axis direction (the x direction) in the graphite crystal lattice may be used, and for example, boron nitride (BN) can also be used.

The graphite plates GL2 and GL3 are the same thermally conductive plates as the graphite plate GL1, but the graphite plate GL2 is rotated by 90 degrees and the graphite plate GL3 is laminated in the same orientation as the graphite plate GL1 (FIG. 14, right side).

The base material 32A which is a graphite laminated plate is an isotropic thermal diffusion material having a high thermal conductivity, and has a thermal conductivity comparable to that of diamond.

Furthermore, although the graphite laminated plate having a three-layer structure has been described, the present invention is not limited thereto. It is preferable that a plurality of graphite plates are laminated in different orientations according to the in-plane anisotropy of the thermal conductivity.

FIG. 15 is a graph illustrating current-output characteristics before and after a PCSEL element 10 is mounted in a surface-emitting laser device 5 of Example 2 (EMB2). Furthermore, the point that the characteristics evaluation was performed by pulse driving at a pulse width of 100 ns and a repetition frequency of 1 kHz (a duty of 0.01%) is the same as in Example 1 and Comparative Example 1.

Also in Example 2 in which the gold-tin alloy (AuSn) was used as the bonding material, it was found that there was no increase in the threshold current of the PCSEL element 10 due to the mounting on the mounting substrate 32, there was no change in the current-output characteristics, and there was no deterioration in the characteristics. Therefore, by using the element-bonding member 31 that relieves the stress applied to the PCSEL element 10, it is possible to significantly suppress the deterioration of the characteristics of the PCSEL element 10, particularly in a case of CW driving.

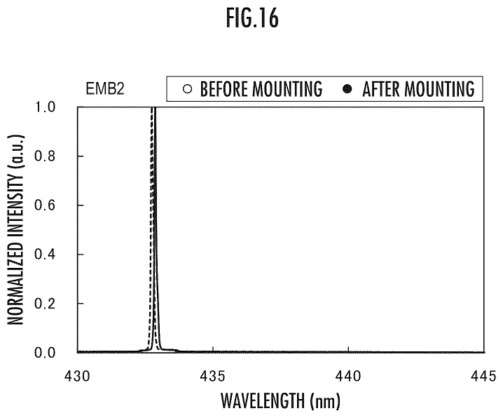

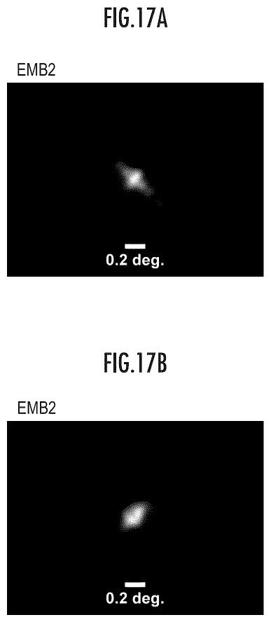

The oscillation spectra before and after the mounting in a case where a current of 3.0 A is applied to the PCSEL element 10 in the surface-emitting laser device 5 of Example 2 are illustrated in FIG. 16. In addition, the beam emission patterns (FFPs) before and after the mounting, respectively, in a case where a current of 3.0 A was applied to the PCSEL element 10 are illustrated in FIGS. 17A and 17B.

From the spectra and the beam emission patterns FFPs before and after the oscillation, it was confirmed that the oscillation occurs in the band edge B mode before and after the mounting.

### 3. Theoretical Analysis and Considerations

(Threshold Current and Change in Oscillation Mode with Respect to Strain Amount)

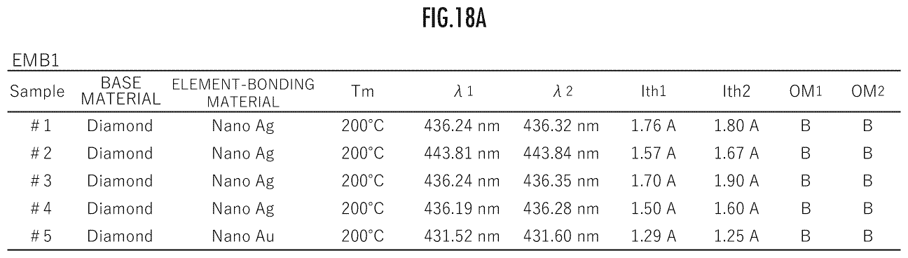

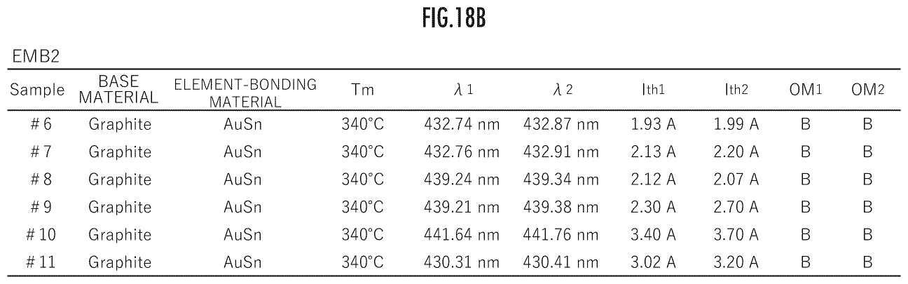

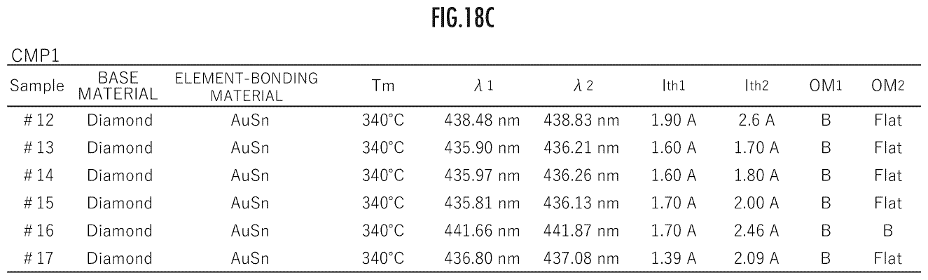

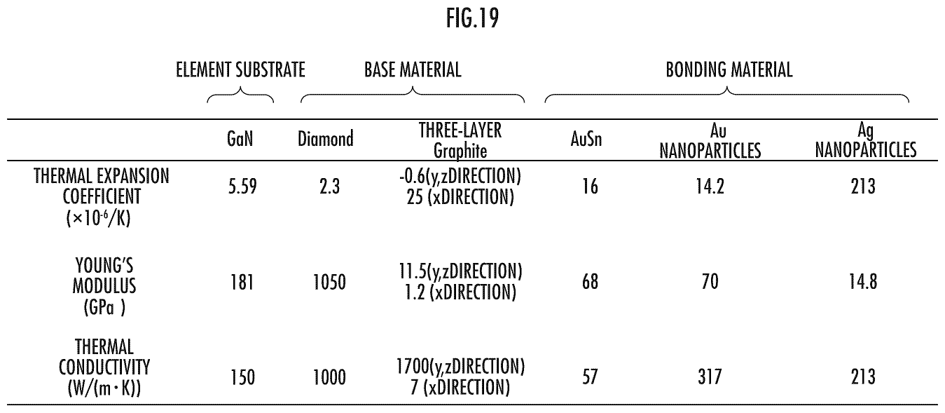

In order to estimate the strain amount that does not deteriorate the laser characteristics, a plurality of samples were manufactured and subjected to element mounting. FIGS. 18A, 18B, and 18C each illustrate the base materials of the mounting substrates of the surface-emitting laser devices, the bonding conditions, and the oscillation characteristics before and after the mounting the PCSEL elements in Example 1 (EMB1), Example 2 (EMB2), and Comparative Example 1 (CMP1).

Furthermore, the mounting temperature (bonding temperature) is represented by Tm, the oscillation wavelengths before and after the mounting are represented by λ₁ and λ₂, respectively, the oscillation threshold values before and after the mounting are represented by Ith₁ and Ith₂, respectively, and the oscillation modes before and after the mounting are represented by OM₁ and OM₂, respectively. Here, in the oscillation modes OM₁ and OM₂ of FIGS. 18A to 18C, B represents an oscillation mode B and Flat represents a flat band mode.

In addition, the physical property values of materials used in Examples 1 and 2 and Comparative Example 1 are illustrated in FIG. 19. Furthermore, the three-layer graphite is based on the technical data of Thermo Fisher Scientific, Inc., and the Ag nanoparticles are based on technical data of NIHON HANDA Co., Ltd. “MAX102”. Since there is no thermal physical property value for Au nanoparticles, the thermal physical property values of Au were used. Furthermore, a submicron Au nanoparticle bonding material (manufactured by TANAKA Precious Metals: AuRoFUSE) was used as the element-bonding material (Nano Ag) of Example 1. Since the bonding material made of nanoparticles is a porous body, the Young's modulus of the submicron Au nanoparticle bonding material is smaller than the value of Au.

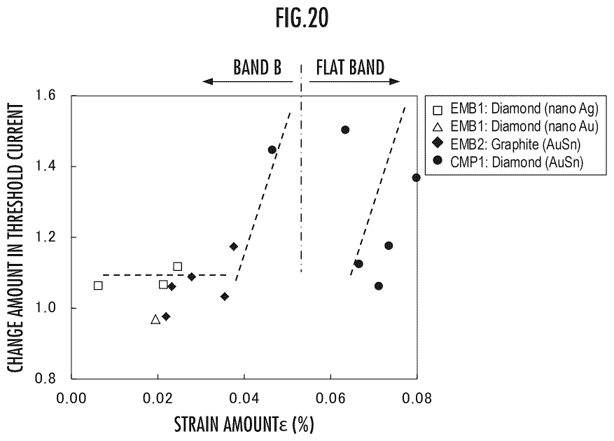

In addition, the graph in which a rate of change of the threshold current with respect to the strain amount ε applied to the PCSEL element by mounting on the mounting substrate (base material) is plotted is illustrated in FIG. 20. Here, the strain amount ε was estimated from the change amount in the oscillation wavelength λ before and after the mounting (ε=ΔPC/PC=Δλ/λ: Expression (4))

In detail, plotted are the values for the case where the base material 32A of the mounting substrate 32 is diamond and the element-bonding member 34 is an Au nanoparticle (Example 1), the case where the base material 32A is diamond and the element-bonding member 34 is an Ag nanoparticle (Example 1), the case where the base material 32A is a graphite laminated plate and the element-bonding member 34 is AuSn (Example 2), and the case where the base material of the mounting substrate is diamond and the element-bonding member is AuSn (Comparative Example 1).

It can be seen from FIG. 20 that in a case where the strain amount ε inherent in the PCSEL element exceeds 0.04%, the threshold current increases. It is considered that this is because the lattice constant (the air-hole period PC) of the photonic crystal layer changes due to the tensile stress generated in the PCSEL element, leading to an increase in the resonator loss.

In addition, in a case where the strain amount ε exceeds 0.05%, the oscillation mode changes from the band edge mode (band B) to the flat band mode. This is considered to be because the application of a strong tensile stress to the photonic crystal layer weakens the two-dimensional coupling of light propagating in the photonic crystal layer, and the resonance through the primary coupling becomes the main oscillation mode.

In a case where the strain amount ε further increases from 0.05%, the threshold current also increases in the flat band mode. In addition, in the flat band mode, the beam quality, that is, the light collecting properties of the beam are significantly deteriorated.

In consideration of both (tensile strain and compressive strain) in a case where the strain amount ε is positive or negative, the strain amount ε is preferably 0.05% or less, and more preferably 0.04% or less. In addition, in consideration of the variation in the threshold current (FIG. 20), the strain amount ε is more preferably 0.03% or less.

### (Stress Applied to PCSEL Element)

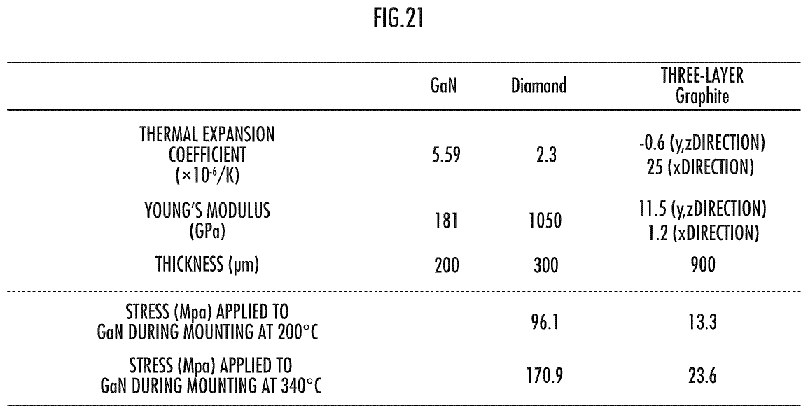

FIG. 21 illustrates stresses σ applied to GaN (that is, the base material of the PCSEL element or the element substrate) at the time of mounting on a mounting substrate in cases of GaN, diamond, and three-layer graphite are used as a base material of the mounting substrate.

Furthermore, the stress σ applied to GaN is given by Expression (5) using the physical property values illustrated in FIG. 19.

$$σ = \{ {t}_{b} {E}_{a} {E}_{b} / ( {t}_{a} {E}_{a} + {t}_{b} {E}_{b} ) \} ( {α}_{a} - {α}_{b} ) Δ T . \qquad ( 5 )$$

Here, for GaN and the base material, the thermal expansion coefficients are denoted by αₐ and α_{b}, respectively, the Young's moduli are denoted by Eₐ and E_{b}, respectively, and the thicknesses are denoted by tₐ and t_{b}, respectively.

As illustrated in FIG. 20, it can be seen that the mounting can be carried out without increasing the oscillation threshold value in a case where the stress during the mounting is 100 MPa or less.

### (Diffraction and Strain Amount of Photonic Crystal Layer)

In a two-dimensional photonic-crystal surface-emitting laser element (PCSEL element), a resonance action is obtained by utilizing the effect that the group velocity becomes zero at the Γ point of the two-dimensional photonic crystal. That is, the resonator of the two-dimensional PCSEL element is a two-dimensional photonic crystal layer. Furthermore, light diffracted by the photonic crystal to the outside of the resonator is necessarily diffracted in a vertical direction with respect to the photonic crystal layer.

As described above, the strain in the photonic crystal layer (air-hole layer) changes the air-hole period and also changes the position of the diffraction surface WS, whereby the interference action between the direct diffracted light Ld and the reflected diffracted light Lr is inhibited. Therefore, it is important to suppress the strain amount ε to an extremely small value.

In addition, the above-described photonic crystal layer 14P has a double lattice structure in which air hole pairs each including a main air hole and a secondary air hole having a smaller size (including an air hole diameter) and a smaller depth than the main air hole are arranged at lattice points. In addition, a centroid position of the secondary air hole in the depth direction of the photonic crystal layer 14P is on a side closer to the active layer than a centroid position of the main air hole.

The strain in the photonic crystal layer (air-hole layer) changes the air-hole period, but the interval between the main air hole and the secondary air hole (the distance between centroids Δx and Δy) also changes due to the strain, so that the effect on the threshold current and the oscillation mode is also large. Therefore, the effect of suppressing the strain amount ε is larger than that in the case of the single lattice.

As described above in detail, according to the present invention, it is possible to provide a photonic-crystal surface-emitting laser device in which an increase in oscillation threshold current and drive current of a mounted PCSEL element is suppressed and which has a stable oscillation mode and excellent beam quality.

Furthermore, the numerical values in the above-described embodiments are merely examples, and can be appropriately modified and applied. Although a PCSEL element having a double lattice structure has been exemplified, the present invention can be applied to a PCSEL element having a single lattice structure, and generally to a PCSEL element having a multiple lattice structure.

In addition, the present invention has been exemplified with respect to a photonic crystal layer in which the air hole has a hexagonal columnar shape, but also can be applied to a case where the air hole of the photonic crystal layer has a columnar shape, a rectangular shape, a polygonal shape, or an irregular columnar shape such as a teardrop shape.

In the present Examples, one PCSEL element 10 is mounted on one mounting substrate 32, but a plurality of PCSEL elements 10 can be mounted on one mounting substrate 32 according to the present invention. For example, a plurality of the PCSEL elements 10 can be arranged in a 3×3 matrix form and mounted on one mounting substrate.

In addition, one PCSEL element mounted on one mounting substrate 32 can be arranged in a matrix form and used as one emitter.

A diamond substrate or a graphite laminated plate was used as the mounting substrate 32, but a composite substrate in which the a and b axis directions in the graphite crystal lattice are disposed to be perpendicular or inclined on the surface of the diamond substrate on which the element is mounted can also be used.

### DESCRIPTION OF REFERENCE NUMERALS

5: surface-emitting laser device
10: PCSEL element
12: element substrate
13: first cladding layer
14: first guide layer
14A: lower guide layer
14B: embedded layer
14K: air hole/air hole pair
14K1/14K2: main air hole/secondary air hole
14P: photonic crystal layer (air-hole layer)
15: active layer
16: second guide layer
17: electron blocking layer
18: second cladding layer
19: contact layer
20A: first electrode
20B: second electrode
20L: light emission region
27: anti-reflection film
29: translucent conductor layer
31: element-bonding member
32: mounting substrate
33: wiring electrode (coating layer)
34: substrate-bonding member
35: heat sink
38: housing
CD1, CD2: centroid
dr: separation distance
Ld: direct diffracted light
Lr: reflected diffracted light
SR: reflection surface.

1. A surface-emitting laser device comprising:
a surface-emitting laser element;
a mounting substrate on which the surface-emitting laser element is placed and which is electrically connected to the surface-emitting laser element; and
an element-bonding member made of a conductive bonding material that bonds the surface-emitting laser element and the mounting substrate and mitigates strain in the surface-emitting laser element due to the mounting substrate,
wherein the surface-emitting laser element includes:
a translucent element substrate,
a first semiconductor layer that is provided on the element substrate,
an active layer that is provided on the first semiconductor layer,
a second semiconductor layer of a conductive type opposite to the first semiconductor layer, provided on the active layer,
a translucent conductor provided on the second semiconductor layer,
an air-hole layer that is a photonic crystal layer included in the first semiconductor layer or the second semiconductor layer and including an air hole disposed with a two-dimensional periodicity in a plane parallel to the active layer, and
a light reflection layer that is provided on the second semiconductor layer and has a reflection surface,
wherein the first semiconductor layer, the active layer, and the second semiconductor layer are group Ill nitride semiconductor layers, and
wherein a light emission surface is provided on a surface side opposite to a surface of the element substrate, on which the first semiconductor layer is provided.

2. The surface-emitting laser device according to claim 1,
wherein in a case where an air-hole period of the air-hole layer of the surface-emitting laser element is denoted by PC₂ and an air-hole period of the air-hole layer before the surface-emitting laser element is bonded to the mounting substrate by the element-bonding member is denoted by PC₁, an change amount in the air-hole period, ΔPC=PC₂−PC₁, is within 0.04%.

3. The surface-emitting laser device according to claim 1, wherein a thermal stress σ that acts between the surface-emitting laser element and the mounting substrate satisfies σ≤100 (MPa).

4. The surface-emitting laser device according to claim 1, wherein the mounting substrate has a base material and a conductive layer provided on the base material, the base material is diamond, and the element-bonding member includes metal nanoparticles.

5. The surface-emitting laser device according to claim 1, wherein the mounting substrate has a base material and a conductive layer provided on the base material, and the base material is a graphite laminated plate.

6. The surface-emitting laser device according to claim 5, wherein the graphite laminated plate is a graphite laminated plate in which a plurality of graphite plates are laminated in different orientations according to in-plane anisotropy of thermal conductivity.

7. The surface-emitting laser device according to claim 1, wherein the air-hole layer has a diffraction surface that diffracts standing-wave light present in the air-hole layer in a direction orthogonal to the air-hole layer, and in a case where a phase difference between a first diffracted light diffracted by the diffraction surface and a second diffracted light diffracted by the diffraction surface and reflected by the reflection surface is denoted by θ (deg), a wavelength of the first diffracted light is denoted by Δ, an average refractive index of a crystal layer from the diffraction surface to the reflection surface is denoted by nₐᵥₑ, and an integer of 0 or more is denoted by m, a separation distance dr between the diffraction surface and the reflection surface is represented by the following expression,
$$d r = \{ ( θ / 360 ) + 0.5 + m \} λ / 2 {n}_{ave} \qquad ( 1 )$$
in which the phase difference θ satisfies,
$$cos θ < 0. \qquad ( 2 )$$

8. The surface-emitting laser device according to claim 1, wherein the air-hole layer has a multiple lattice structure in which air hole pairs each including a main air hole and a secondary air hole having a smaller size and a smaller depth than the main air hole are arranged at each of lattice points.

9. The surface-emitting laser device according to claim 1, wherein the air-hole layer has a thickness such that an optical path length of the air-hole layer is less than one wavelength.

10. The surface-emitting laser device according to claim 1, wherein the air-hole layer has a multiple lattice structure in which air hole pairs each including a main air hole and a secondary air hole having a smaller size and a smaller depth than the main air hole are arranged at each of lattice points, and a centroid position of the secondary air hole in a depth direction of the air-hole layer is on a side closer to the active layer than a centroid position of the main air hole.

11. The surface-emitting laser device according to claim 10, wherein in a case where an air-hole period of the air-hole layer of the surface-emitting laser element is denoted by PC₂ and an air-hole period of the air-hole layer before the surface-emitting laser element is bonded to the mounting substrate by the element-bonding member is denoted by PC₁, a change amount in the air-hole period, ΔPC=PC₂−PC₁, is 0.02% or more and 0.05% or less.
